(19) United States
(12) Patent Application Publication
(10) Pub. No.: US 2020/0096828 A1
(43) Pub. Date: Mar. 26, 2020

(54) DISPLAY DEVICE

(71) Applicant: Samsung Display Co., Ltd., Yongin-si (KR)

(72) Inventor: Sihyun AHN, Hwaseong-si (KR)

(21) Appl. No.: 16/528,119

(22) Filed: Jul. 31, 2019

(30) Foreign Application Priority Data
Sep. 20, 2018 (KR) 10-2018-0112834

(51) Int. Cl. G02F 1/1362

(52) U.S. Cl. CPC G02F 1/136286; H01L 27/124; G02F 1/136213

(57) ABSTRACT

A display device includes a first pixel electrode, a second pixel electrode spaced apart from the first pixel electrode in a first direction, a third pixel electrode spaced apart from the second pixel electrode in the first direction, a first gate line electrically connected to the first pixel electrode, a second gate line electrically connected to the second pixel electrode, and a third gate line electrically connected to the third pixel electrode. The first gate line may be disposed between the second pixel electrode and the third pixel electrode.

### CROSS-REFERENCE TO RELATED APPLICATION

This patent application claims priority to and the benefit of Korean Patent Application No. 10-2018-0112834, filed on Sep. 20, 2018, the entire content of which is hereby incorporated by reference.

### BACKGROUND

### 1. Field

The present disclosure herein relates to a display device.

### 2. Description of the Related Art

A liquid crystal display device includes a liquid crystal display panel having two substrates facing each other and a liquid crystal layer disposed between the two substrates. The liquid crystal display device applies a voltage to electric-field-generating-electrodes to generate an electric field in the liquid crystal layer. Accordingly, the orientation direction of liquid crystal molecules of the liquid crystal layer is determined (e.g., by the electric field), and an image is displayed by controlling the polarization of incident light.

The electric field generating electrodes may include a pixel electrode and a common electrode. A pixel voltage may be provided to the pixel electrode, and a common voltage may be applied to the common electrode. A parasitic capacitor (parasitic capacitance), a storage capacitor, and a liquid crystal capacitor may be connected in parallel to the pixel electrode. The pixel voltage is desirably (e.g., preferably) maintained uniformly during one frame, but the pixel voltage may also be varied by various factors. For example, charges of the parasitic capacitor, the storage capacitor and the liquid crystal capacitor may be redistributed by the changes (e.g., level changes) of voltage applied to lines adjacent to the pixel electrode, and accordingly, the pixel voltage may be reduced. Such variation in the pixel voltage may cause deterioration of the display image quality.

### SUMMARY

An aspect according to embodiments of the present disclosure is directed toward a display device having improved transmittance and display quality.

According to an embodiment of the inventive concept, a display device includes a first pixel electrode, a second pixel electrode spaced apart from the first pixel electrode in a first direction, a third pixel electrode spaced apart from the second pixel electrode in the first direction, a first gate line electrically connected to the first pixel electrode, a second gate line electrically connected to the second pixel electrode, and a third gate line electrically connected to the third pixel electrode, wherein the first gate line may be between the second pixel electrode and the third pixel electrode.

In an embodiment, the first pixel electrode may not overlap with the first gate line when viewed on a plane.

In an embodiment, the third pixel electrode may overlap with the first gate line and the second gate line when viewed on a plane.

In an embodiment, the display device may further include a first storage capacitor between the third pixel electrode and the first gate line, and a second storage capacitor between the third pixel electrode and the second gate line.

In an embodiment, the first gate line may overlap with the second pixel electrode and the third pixel electrode when viewed on a plane.

In an embodiment, the display device may further include a first auxiliary gate line and a second auxiliary gate line facing each other and with the first pixel electrode therebetween.

In an embodiment, each of the first auxiliary gate line, the second auxiliary gate line, the first gate line, the second gate line, and the third gate line may be extended in a second direction crossing the first direction.

In an embodiment, the display device may further include a gate driver configured to provide a gate signal to each of the first gate line, the second gate line, and the third gate line, and the gate driver may include a plurality of gate stages.

In an embodiment, the first gate line, the second gate line, and the third gate line may be electrically connected to the plurality of gate stages in a one-to-one correspondence, and each of the first auxiliary gate line and the second auxiliary gate line may be configured to receive a ground voltage.

In an embodiment, the second auxiliary gate line may be between the first pixel electrode and the second pixel electrode, electrically connected to one gate stage among the plurality of gate stages, and receive the gate signal.

In an embodiment, the display device may further include a fourth pixel electrode spaced apart from the third pixel electrode in the first direction, a fifth pixel electrode spaced apart from the fourth pixel electrode in the first direction, a sixth pixel electrode spaced apart from the fifth pixel electrode in the first direction, a first data line electrically connected to the first pixel electrode, the second pixel electrode, and the third pixel electrode and configured to receive a data voltage of a first polarity, and a second data line electrically connected to the fourth pixel electrode, the fifth pixel electrode, and the sixth pixel electrode and configured to receive a data voltage of a second polarity different from the first polarity, wherein the first data line and the second data line may have a first partial line extended in the first direction, a second partial line extended from the first partial line in the second direction crossing the first direction, and a third partial line extended from the second partial line in the first direction, and the second partial line may be in a region between the fourth pixel electrode and the fifth pixel electrode.

In an embodiment, the second gate line may be between the third pixel electrode and the fourth pixel electrode and overlap with the third pixel electrode and the fourth pixel electrode when viewed on a plane, and the third gate line may be between the fourth pixel electrode and the fifth pixel electrode and overlap with the fourth pixel electrode and the fifth pixel electrode when viewed on a plane.

In an embodiment, a first width of the first pixel electrode parallel to the first direction may be less than a second width of the first pixel electrode parallel to the second direction crossing the first direction.

In an embodiment, the first pixel electrode may include a first boundary electrode extended in the second direction crossing the first direction, a second boundary electrode extended in the first direction, and a plurality of branch electrodes extended from a corresponding one of the first boundary electrode and the second boundary electrode in a direction crossing the first direction and the second direction.

In an embodiment, a length of the first boundary electrode may be greater than a length of the second boundary electrode.

In an embodiment of the inventive concept, a display device includes a plurality of pixel electrodes arranged with each other along a first direction, a plurality of pixel transistors electrically connected to the plurality of pixel electrodes in a one-to-one correspondence, and a plurality of gate lines electrically connected to the plurality of pixel transistors in a one-to-one correspondence, wherein the plurality of pixel electrodes may include a first pixel electrode and a second pixel electrode, the plurality of pixel transistors may include a first pixel transistor electrically connected to the first pixel electrode and a second pixel transistor electrically connected to the second pixel electrode, and the plurality of gate lines may include a first gate line electrically connected to the first pixel transistor and a second gate line electrically connected to the second pixel transistor, wherein the first pixel transistor may be adjacent to the second pixel electrode and the first gate line may be spaced apart from the first pixel electrode and with the second pixel electrode therebetween.

In an embodiment, the display device may further include a first auxiliary gate line and a second auxiliary gate line facing each other and with the first pixel electrode therebetween.

In an embodiment, the plurality of gate lines may be configured to receive a gate signal, and the first auxiliary gate line and the second auxiliary gate line may be configured to receive a ground voltage.

In an embodiment, the second auxiliary gate line may be between the first pixel electrode and the second pixel electrode and overlap with the first pixel electrode and the second pixel electrode when viewed on a plane, the plurality of gate lines and the second auxiliary gate line may receive a gate signal, and the first auxiliary gate line may be configured to receive a ground voltage.

In an embodiment, the first pixel electrode may include a first boundary electrode extended in a second direction crossing the first direction, a second boundary electrode extended in the first direction, and a plurality of branch electrodes extended from each of the first boundary electrode and the second boundary electrode in a direction crossing the first direction and the second direction, and a length of the first boundary electrode may be greater than a length of the second boundary electrode.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view of a display device according to an embodiment of the inventive concept;

FIG. 2 is a block diagram of a display device according to an embodiment of the inventive concept;

FIG. 3 is a block diagram showing an enlarged view of a portion of FIG. 2;

FIG. 4 is a cross-sectional view of a display panel according to an embodiment of the inventive concept;

FIG. 5 is a plan view showing an enlarged view of a portion of a display panel according to an embodiment of the inventive concept;

FIG. 6 is an equivalent circuit diagram of a pixel according to an embodiment of the inventive concept;

FIG. 7 is a cross-sectional view taken along the line I-I′ illustrated in FIG. 5;

FIG. 8 is a block diagram of a gate driver according to an embodiment of the inventive concept;

FIG. 9 is a block diagram showing an enlarged view of a portion of a display panel according to an embodiment of the inventive concept;

FIG. 10 is a block diagram showing an enlarged view of a portion of a display panel according to an embodiment of the inventive concept; and

FIG. 11 is a block diagram showing an enlarged view of a portion of a display panel according to an embodiment of the inventive concept.

### DETAILED DESCRIPTION

In the present disclosure, when an element (or a region, a layer, a portion, etc.) is disclosed as being “on,” “connected to,” or “coupled to” another element, the element may be directly disposed on/connected to/coupled to the other element, or one or more intervening elements may be disposed therebetween.

Like reference numerals refer to like elements. Also, in the drawings, the thickness, the ratio, and the dimensions of elements may be exaggerated for an effective description of the technical contents.

The term “and/or” includes all combinations of one or more of which associated configurations may define. The use of “may” when describing embodiments of the inventive concept refers to “one or more embodiments of the inventive concept.” Also, the terms “exemplary” and “exemplarily” are intended to refer to an example or illustration.

It will be understood that, although the terms “first”, “second”, etc., may be used herein to describe various elements, these elements should not be limited by these terms. These terms are only used to distinguish one element from another. For example, a first element could be termed a second element, and, similarly, a second element could be termed a first element, without departing from the scope of example embodiments of the inventive concept. The terms of a singular form may include plural forms unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the inventive concept belongs. Also, terms such as those defined in commonly used dictionaries should be interpreted as having meanings that are consistent with the meanings in the context of the relevant art unless they are interpreted in an ideal or overly formal sense.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Hereinafter, exemplary embodiments of the inventive concept will be described with reference to the accompanying drawings.

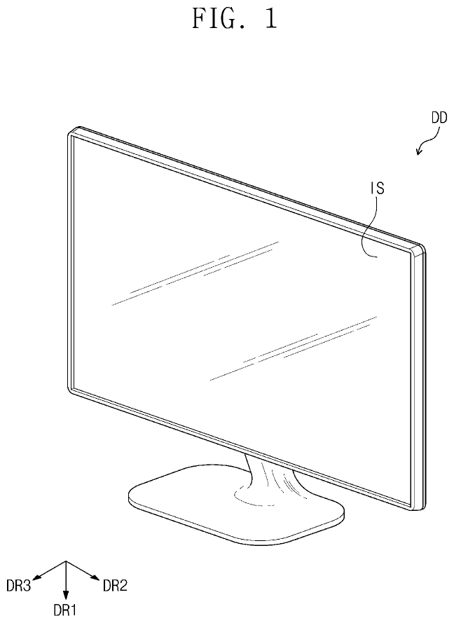

FIG. 1 is a perspective view of a display device according to an embodiment of the inventive concept.

Referring to FIG. 1, a display device DD may display an image through a display region IS. In FIG. 1, the display region IS is exemplarily illustrated as being provided on a surface defined by a first direction DR1 and a second direction DR2 crossing the first direction DR1. However, in another embodiment of the inventive concept, a display region of a display device may be provided on a bent (e.g., curved) surface.

The thickness direction of the display device DD is indicated by a third direction DR3. The directions indicated by the first to third directions DR1, DR2, and DR3 are a relative concept, and therefore, may be converted to other directions. In the present disclosure, the phrase “when viewed on a plane” may refer to when viewed from the third direction DR3. Also, the term “thickness direction” may refer to the third direction DR3.

In FIG. 1, the display device DD is exemplarily illustrated as being a television. However, the display device DD may be utilized for large electronic devices (such as a monitor, and/or an external advertisement board), and also for small and medium-sized electronic devices (such as a personal computer, a notebook computer, a personal digital terminal, a car navigation system unit, a game machine, a smart phone, a tablet, and/or a camera). It should be understood that these are merely exemplary embodiments, and the display device DD may be employed in other suitable electronic devices without departing from the inventive concept.

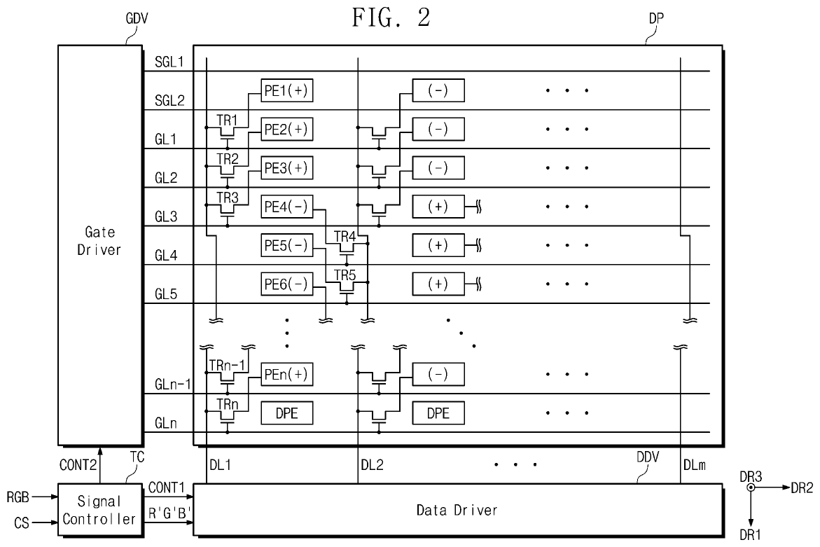

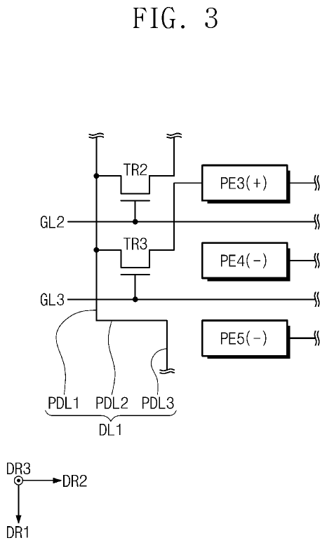

FIG. 2 is a block diagram of the display device according to an embodiment of the inventive concept, and FIG. 3 is a block diagram showing an enlarged view of a portion of FIG. 2.

Referring to FIG. 2, the display device DD may include a display panel DP, a signal controller TC (or a timing controller), a data driver DDV, and a gate driver GDV. The signal controller TC, the data driver DDV, and the gate driver GDV may be composed of circuits.

The display panel DP may be a liquid crystal display panel. The display device DD may further include a backlight unit which provides light to the display panel DP. The display panel DP may display an image by controlling the transmittance of light generated from the backlight unit.

The display panel may include a plurality of data lines DL1-DLm, a plurality of gate lines GL1-GLn, a first auxiliary gate line SGL1, a second auxiliary gate line SGL2, dummy pixel electrodes DPE, and a plurality of pixel electrodes PE1-PEn.

The plurality of data lines DL1-DLm are extended in the first direction DR1, and may be arranged along the second direction DR2 crossing the first direction DR1. The plurality of gate lines GL1-GLn are extended in the second direction DR2, and may be arranged along the first direction DR1. In the present disclosure, the description that each configuration is extended along the first direction DR1 or the second direction DR2 only indicates the direction in which each configuration is extended, and each configuration is not limited to being parallel to the first direction DR1 or the second direction DR2.

The plurality of pixel electrodes PE1-PEn may be disposed on a plane of the display panel DP according to a set or predetermined rule. Each of the pixels including the plurality of pixel electrodes PE1-PEn may display one of the primary colors or one of the mixed colors thereof. The primary colors may include red, green, and/or blue, and the mixed colors may include various suitable colors such as yellow, cyan, magenta, and/or white. However, the colors displayed by each of the plurality of pixels are not limited thereto.

The plurality of pixel electrodes PE1-PEn may be disposed along the first direction DR1 and the second direction DR2. In FIG. 2, for brevity, only pixel electrodes PE1-PEn arranged in the first column among the plurality of pixel electrodes are illustrated with reference numerals, but the inventive concept is not limited thereto.

The dummy pixel electrodes DPE may be arranged below the last row of the plurality of pixel electrodes PE1-PEn. In FIG. 2, the dummy pixel electrodes DPE are exemplarily illustrated as being arranged in one row, but the inventive concept is not limited thereto. The dummy pixel electrodes DPE may be arranged in a plurality of rows. In addition, in another embodiment of the inventive concept, the dummy pixel electrodes DPE may be disposed surrounding the display region IS (see FIG. 1). The dummy pixel electrodes DPE may be disposed in a region that is not viewed by a user.

The pixel transistors TR1-TRn may be electrically connected to the pixel electrodes PE1-PEn in a one-to-one correspondence. In FIG. 2, among the plurality of the pixel transistors TR1-TRn, only the pixel transistors TR1-TRn electrically connected to the pixel electrodes PE1-PEn arranged in the first column are illustrated with reference numerals.

Each of the pixel transistors TR1-TRn may be electrically connected to one corresponding gate line and one corresponding data line. For example, a first pixel transistor TR1 may be electrically connected to a first gate line GL1 and a first data line DL1. Accordingly, the pixel electrodes PE1-PEn may be electrically connected to corresponding gate lines among the gate lines GL1-GLn and corresponding data lines among the data lines DL1-DLm.

A first pixel electrode PE1 may be a pixel electrode disposed in the first row and the first column. A second pixel electrode PE2 may be a pixel electrode spaced apart from the first pixel electrode PE1 in the first direction DR1. A third pixel electrode PE3 may be a pixel electrode spaced apart from the second pixel electrode PE2 in the first direction DR1.

According to an embodiment of the inventive concept, the first gate line GL1 connected to the first pixel electrode PE1 may be disposed between the second pixel electrode PE2 and the third pixel electrode PE3. That is, the first gate line GL1 electrically connected to the first pixel electrode PE1 is disposed to be spaced apart from the first pixel electrode PE1. Also, the first pixel transistor TR1 connected to the first pixel electrode PE1 may be disposed adjacent to the second pixel electrode PE2.

In FIG. 2, the second pixel electrode PE2 is exemplarily illustrated as being disposed between the first gate line GL1 and the first pixel electrode PE1, but the inventive concept is not limited thereto. For example, in another embodiment of the inventive concept, the second pixel electrode PE2 and the third pixel electrode PE3 may be disposed between the first pixel electrode PE1 and the first gate line GL1.

The first auxiliary gate line SGL1 and the second auxiliary gate line SGL2 are respectively extended in the second direction DR2, and may be disposed to be spaced apart from each other in the first direction DR1. The first auxiliary gate line SGL1 and the second auxiliary gate line SGL2 may be disposed to be spaced apart from each other with the first pixel electrode PE1 therebetween. On a plane (e.g., when viewed on a plane), a portion of each of the first auxiliary gate line SGL1 and the second auxiliary gate line SGL2 may overlap with the first pixel electrode PEI.

The first data line DL1 may receive a data voltage of a first polarity, and a second data line DL2 may receive a data voltage of a second polarity. The first polarity and the second polarity may be different from each other. In FIG. 2, the first polarity is exemplarily illustrated as being a positive polarity data voltage having a positive value with respect to a common voltage, and the second polarity is exemplarily illustrated as being a negative polarity data voltage having a negative value with respect to a common voltage. The data driver DDV may generate data voltages that are inverted per frame interval unit in response to an inverted signal.

Some pixel electrodes among the pixel electrodes PE1-PEn disposed in one row (e.g., in the same row or same column, such as PE1 to PE3) may be electrically connected to the first data line DL1, and some other pixel electrodes among the same (e.g., in the same row or same column, such as PE4 to PE6) may be electrically connected to the second data line DL2. In FIG. 2, a unit of three pixel electrodes is exemplarily illustrated as being connected to the first data line DL1 or the second data line DL2 alternately (e.g., in an alternating fashion). However, the inventive concept is not limited thereto. For example, in another embodiment of the inventive concept, a unit of one pixel electrode may be connected to the first data line DL1 or the second data line DL2 alternately (e.g., in an alternating fashion), or a unit of two pixel electrodes may be connected to the first data line DL1 or the second data line DL2 alternately (e.g., in an alternating fashion).

Referring to FIG. 3, the first data line DL1 may include a first portion line PDL1, a second portion line PDL2, and a third portion line PDL3. The first portion line PDL1 may be extended in the first direction DR1, the second portion line PDL2 may be extended from the first portion line PDL1 in the second direction DR2, and the third portion line PDL3 may be extended from the second portion line PDL2 in the first direction DR1. Also, although not illustrated in FIG. 3, the second data line DL2 may have substantially the same structure as the first data line DL1. The second portion line PDL2 may be disposed in a region between a fourth pixel electrode PE4 and a fifth pixel electrode PE5.

Referring back to FIG. 2, the polarity a data voltage applied to the third pixel electrode PE3 is different from the polarity of a data voltage applied to the fourth pixel electrode PE4. In a region adjacent to the fourth pixel electrode PE4, a third pixel transistor TR3 electrically connected to the third pixel electrode PE3 is disposed. Accordingly, when the second portion line PDL2 is disposed in a region between the second pixel electrode PE2 and the third pixel electrode PE3, the second portion line PDL2 may overlap with a portion (e.g., of the circuit) connecting the third pixel electrode PE3 and the third pixel transistor TR3. A phenomenon in which a signal is distorted due to overlapping of signal lines may occur. However, according to an embodiment of the inventive concept, the second portion line PDL2 may be disposed between the fourth pixel electrode PE4 and the fifth pixel electrode PE5. Accordingly, the portion connecting the third pixel electrode PE3 and the third pixel transistor TR3 may not overlap with the first data line DL1. Accordingly, the phenomenon in which a signal is distorted due to overlapping of the connecting portion and the first data line DL1 may be prevented or substantially prevented from occurring.

The signal controller TC receives an image data RGB provided from the outside. The signal controller TC converts the image data RGB so as to conform to an operation of the display panel DP and generates a converted image data R′G′B′, and then outputs the converted image data R′G′B′ to the data driver DDV.

In addition, the signal controller TC may receive a control signal CS provided from the outside. Examples of the control signal CS may include a vertical synchronization signal, a horizontal synchronization signal, a main clock signal, a data enable signal, and/or the like. The signal controller TC provides a first control signal CONT1 to the data driver DDV, and provides a second control signal CONT2 to the gate driver GDV. The first control signal CONT1 is a signal for controlling the data driver DDV, and the second control signal CONT2 is a signal for controlling the gate driver GDV.

The data driver DDV may drive the plurality of data lines DL1-DLm in response to the first control signal CONT1 received from the signal controller TC. The data driver DDV may be implemented as an independent integrated circuit and electrically connected to one side of the display panel DP, or may be directly mounted on the display panel DP. Also, the data driver DDV may be implemented as a single chip or may include a plurality of chips.

The gate driver GDV drives the plurality of gate lines GL1-GLn in response to the second control signal CONT2 received from the signal controller TC. The gate driver GDV may be integrated in a set or predetermined region of the display panel DP. In this case, the gate driver GDV may include a plurality of thin film transistors formed through a Low Temperature Polycrystalline Silicon (LTPS) process or a Low Temperature Polycrystalline Oxide (LTPO) process. Also, in another embodiment of the inventive concept, the gate driver GDV may be implemented as an independent integrated circuit and electrically connected to one side of the display panel DP.

When a gate-on voltage is being applied to one of the plurality of gate lines GL1-GLn, the pixel transistor of each of the pixels of the row connected thereto (connected to the one of the plurality of gate lines) is turned on. At this time (e.g., at the same time), the data driver DDV provides data driving signals to the data lines DL1-DLm. The data driving signals provided to the data lines DL1-DLm are applied to a corresponding pixel through a turned-on switching transistor. The data driving signals may be analog voltages corresponding to gray scale values (gray levels) of the image data.

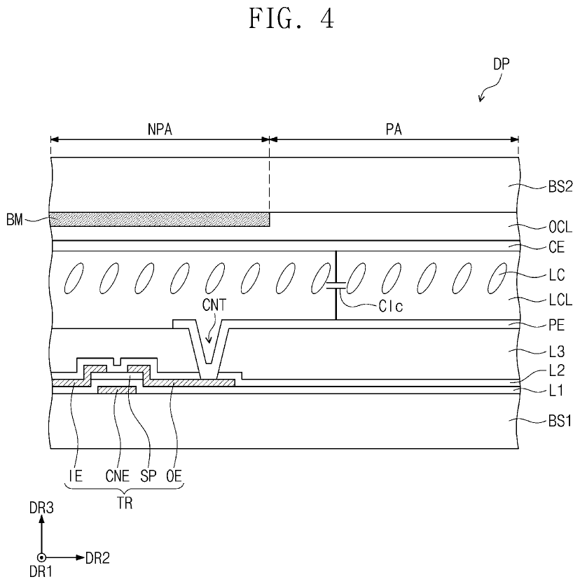

FIG. 4 is a cross-sectional view of a display panel according to an embodiment of the inventive concept.

Referring to FIG. 4, the display device DD (see FIG. 1) may include the display panel DP and a backlight unit. The backlight unit may be disposed either on an upper portion or a lower portion of the display panel DP and provide light to the display panel DP. Also, in another embodiment of the inventive concept, the display device DD may not include a backlight unit. In this case, the display panel DP may display an image by controlling the transmittance of light generated from the outside.

The display panel DP may include a first base substrate BS1, a second base substrate BS2, a pixel transistor TR, a pixel electrode PE, a common electrode CE, a liquid crystal layer LCL, and a light blocking layer BM.

The first base substrate BS1 and the second base substrate BS2 may be optically transparent. Accordingly, light generated from the backlight unit may transmit through the first base substrate BS1 and reach (e.g., easily reach) the liquid crystal layer LCL, and the light transmitted through the liquid crystal layer LCL may transmit through the second base substrate BS2.

The first base substrate BS1 and the second base substrate BS2 may include an insulating material. For example, the first base substrate BS1 and the second base substrate BS2 may be a silicon substrate, a plastic substrate, an insulating film, a laminated structure, a glass substrate, and/or the like. The laminated structure may include a plurality of insulating layers.

The pixel transistor TR may include control electrode CNE, an input electrode IE, an output electrode OE, and a semiconductor pattern SP.

The control electrode CNE may be disposed on the first base substrate BS1. The control electrode CNE may include a conductive material. For example, the conductive material may be a metal material, and the metal material may include, for example, molybdenum, silver, titanium, copper, aluminum, or an alloy thereof.

A first insulating layer L1 is disposed on the first base substrate BS1, and may cover the control electrode CNE. That is, the control electrode CNE may be disposed between the first insulating layer L1 and the first base substrate BS1.

On the first insulating layer L1, the semiconductor pattern SP may be disposed. On a cross section, the semiconductor pattern SP may be disposed to be spaced apart from the control electrode CNE with the first insulating layer L1 therebetween.

The semiconductor pattern SP may include a semiconductor material. The semiconductor material may include at least one of, for example, amorphous silicon, polycrystalline silicon, single crystal silicon, an oxide semiconductor, or a compound semiconductor.

On the semiconductor pattern SP, the input electrode IE, and the output electrode OE may be disposed.

A second insulating layer L2 is disposed on the first insulating layer L1, and may cover the semiconductor pattern SP, the input electrode IE, and the output electrode OE. That is, the semiconductor pattern SP, the input electrode IE, and the output electrode OE may be disposed between the first insulating layer L1 and the second insulating layer L2.

On the second insulating layer L2, a third insulating layer L3 may be disposed. The third insulating layer L3 may be a color filter. For example, when the third insulating layer L3 is a red color filter, the third insulating layer L3 may transmit light of the red wavelength region, and block light of other wavelength regions.

In FIG. 4, the third insulating layer L3 is exemplarily illustrated as being a color filter, but the inventive concept is not limited thereto. For example, in another embodiment of the inventive concept, the third insulating layer L3 may be a transparent insulating layer for providing a flat surface, and a color filter may be formed on the second base substrate BS2. In addition, in another embodiment of the inventive concept, a color filter may be substituted with a wavelength converting layer. The wavelength converting layer may include a quantum dot and/or a quantum rod.

In addition, although not illustrated in FIG. 4, a capping layer for covering the third insulating layer L3 may be further provided. The capping layer may include an inorganic material, for example, silicon nitride and/or silicon oxide. The capping layer may cover the third insulating layer L3 to protect the third insulating layer L3. In addition, an opening may be provided on the capping layer through which gas generated in the third insulating layer L3 may be emitted.

The pixel electrode PE may be electrically connected to the pixel transistor TR. On the second insulating layer L2 and the third insulating layer L3, a contact hole CNT is defined. The contact hole CNT may be provided by removing a portion of the second insulating layer L2 and the third insulating layer L3. The contact hole CNT may expose configurations disposed under the second insulating layer L2 and the third insulating layer L3. For example, the contact hole CNT may expose the output electrode OE. The pixel electrode PE may be electrically connected to the output electrode OE exposed by the contact hole CNT. The pixel electrode PE may be electrically connected to the output electrode OE by being in direct contact thereto, or may be indirectly connected to the output electrode OE through a conductive member disposed between the pixel electrode PE and the output electrode OE.

On the pixel electrode, the liquid crystal layer LCL may be disposed. The liquid crystal layer LCL may include a plurality of liquid crystal molecules LC. The arrangement of the liquid crystal molecules LC may be changed according to an electric field formed between the common electrode CE and the pixel electrode PE.

On the liquid crystal layer LCL, the second base substrate BS2 may be disposed. On one surface of the second base substrate BS2, e.g., the surface facing the first base substrate BS1, the light blocking layer BM may be disposed. The light blocking layer BM may overlap with the pixel transistor TR on a plane.

A region covered by the light blocking layer BM may be defined as a non-light emitting area NPA, and a region not covered by the light blocking layer BM may be defined as a light emitting area PA. Light having passed through the liquid crystal layer LCL may be emitted to the outside of the second base substrate BS2 through the light emitting area PA.

On one surface of the second base substrate BS2, e.g., the surface facing the first base substrate BS1, a planarization layer OCL covering the light blocking layer BM may be disposed. The planarization layer OCL may include an organic material. On the planarization layer OCL, the common electrode CE may be disposed.

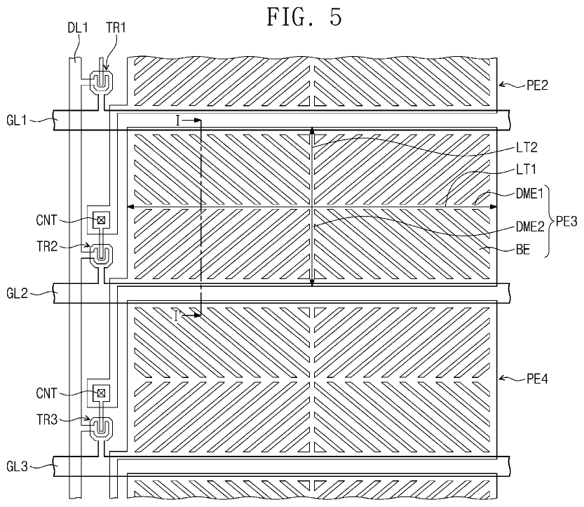

FIG. 5 is a plan view showing an enlarged view of a portion of a display panel according to an embodiment of the inventive concept.

In FIG. 5, a portion of the second pixel electrode PE2, the third pixel electrode PE3, the fourth pixel electrode PE4, and the fifth pixel electrode PE5 are illustrated.

The first gate line GL1 may be disposed between the second pixel electrode PE2 and the third pixel electrode PE3, a second gate line GL2 may be disposed between the third pixel electrode PE3 and the fourth pixel electrode PE4, and a third gate line GL3 may be disposed between the fourth pixel electrode PE4 and the fifth pixel electrode PE5. The first gate line GL1 is a gate line electrically connected to the first pixel electrode PE1 (see FIG. 2), the second gate line GL2 is a gate line electrically connected to the second pixel electrode PE2, and the third gate line GL3 is a gate line electrically connected to the third pixel electrode PE3.

According to an embodiment of the inventive concept, one of the pixel electrode and one of the gate line electrically connected to the one of the pixel electrode are disposed to be spaced apart from each other on a plane (e.g., when viewed on a plane), and may not overlap with each other. Hereinafter, the third pixel electrode PE3 will be exemplarily described.

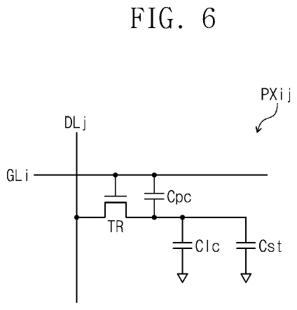

The third pixel electrode PE3 may overlap with the first gate line GL1 and the second gate line GL2 on a plane. That is, the third pixel electrode PE3 may not overlap with the third gate line GL3, which is electrically connected to the third pixel electrode PE3. Accordingly, a parasitic capacitor (parasitic capacitance) Cpc (see FIG. 6) may be prevented or substantially prevented from being formed between the third pixel electrode PE3 and the third gate line GL3.

Although only the third pixel electrode PE3 has been described as an example in the present disclosure, a parasitic capacitor (parasitic capacitance) may also be prevented or substantially prevented from being formed between other pixel electrodes and the respective gate lines connected to the pixel electrodes by not overlapping the pixel electrodes with the respective gate lines connected to the pixel electrodes.

The pixel electrodes may have substantially the same shape as the third pixel electrode PE3. Therefore, the shape of the third pixel electrode PE3 will be described as a representative example.

The third pixel electrode PE3 may have a shape elongated in a direction in which the third gate line GL3 is extended. For example, the third pixel electrode PE3 may have a shape in which the width thereof in the lateral direction is larger than the width thereof in the longitudinal direction. The longitudinal direction may be the first direction DR1, and the lateral direction may be the second direction DR2.

The third pixel electrode PE3 may include a first boundary electrode DME1, a second boundary electrode DME2, and a plurality of branch electrodes BE. The first boundary electrode DME1 may be extended along the second direction DR2, and the second boundary electrode DME2 may be extended in the first direction DR1. A first length LT1 of the first boundary electrode DME1 may be greater than a second length LT2 of the second boundary electrode DME2. The first boundary electrode DME1 and the second boundary electrode DME2 may form a cross shape by crossing each other.

Each of the branch electrodes BE may be extended in a direction crossing the first direction DR1 and the second direction DR2 from a corresponding one of the first boundary electrode DME1 and the second boundary electrode DME2 (e.g., a plurality of the branch electrodes may be extended from each of the first boundary electrode DME1 and the second boundary electrode DME2).

The third pixel electrode PE3 may be divided into four domains by the first boundary electrode DME1 and the second boundary electrode DME2. Lateral visibility may be improved by evenly distributing directions in which the liquid crystal molecules LC are tilted by providing the domains in a plurality.

FIG. 6 is an equivalent circuit diagram of a pixel according to an embodiment of the inventive concept.

Referring to FIG. 4 and FIG. 6, an equivalent circuit diagram of one pixel PXij connected to a gate line GLi and a data line DLj is exemplarily illustrated.

The pixel PXij may include the pixel transistor TR, a liquid crystal capacitor Clc, and a storage capacitor Cst. To facilitate understanding, a parasitic capacitor Cpc formed in the pixel PXij is also illustrated.

The control electrode CNE of the pixel transistor TR may be connected to the gate line GLi, the input electrode IE of the pixel transistor TR may be connected to the data line DLi, and the output electrode OE of the pixel transistor TR may be connected to the pixel electrode PE.

When the pixel transistor TR is turned on by a gate signal applied to the gate line GLi, a data signal provided to the data line DLi may be applied to the pixel electrode PE as a pixel voltage.

The liquid crystal capacitor Clc may include the pixel electrode PE electrically connected to the pixel transistor TR, the liquid crystal layer LCL, and the common electrode CE. The liquid crystal capacitor Clc may serve to display a gray scale value (gray level) corresponding to a data signal applied to the pixel electrode PE. That is, a pixel voltage corresponding to the data signal may be applied to one electrode of each of the liquid crystal capacitor CIc and the storage capacitor Cst by being connected to the output electrode OE of the pixel transistor TR, and a common voltage may be applied to the other electrode of each of the liquid crystal capacitor CIc and the storage capacitor Cst.

The parasitic capacitor Cpc may be formed between the control electrode CNE of the pixel transistor TR and the output electrode OE of the pixel transistor TR. Accordingly, the parasitic capacitor Cpc, the storage capacitor Cst, and the liquid crystal capacitor CIc may be connected in parallel to the pixel electrode PE.

When the level (e.g., voltage level) of a signal applied to the gate line GLi is changed, charges may be redistributed between capacitors connected to the pixel electrode PE due to voltage variation of a gate signal, and accordingly, the pixel voltage may be varied. The amount of variation of the pixel voltage may be referred to as a kickback voltage Vkb. The kickback voltage Vkb may be calculated by the following equation.

Vkb=Cpc/(Cpc+Cst+Clc)*Voltage variation of gate signal

According to an embodiment of the inventive concept, the gate line GLi electrically connected to the pixel electrode PE may not overlap with the pixel electrode PE so that the parasitic capacitor Cpc generated between the gate line GLi and the pixel electrode PE may be minimized or reduced. Accordingly, the magnitude of the kickback voltage Vkb may be reduced, and the display quality of the display device DD (see FIG. 1) may be improved.

In addition, according to an embodiment of the inventive concept, even when an overlay deviation (e.g., deviation in the position) of the pixel electrode PE is generated, because the pixel electrode PE does not overlap with the gate line GLi which is electrically connected to the pixel electrode PE, the change of the parasitic capacitor Cpc due to the overlay deviation may be minimized or reduced, so that the deviation of the kickback voltage Vkb may also be minimized or reduced. Accordingly, a phenomenon in which a residual image or a yellowish color at a low gray scale is viewed on the display device DD (see FIG. 1) may be prevented or substantially prevented.

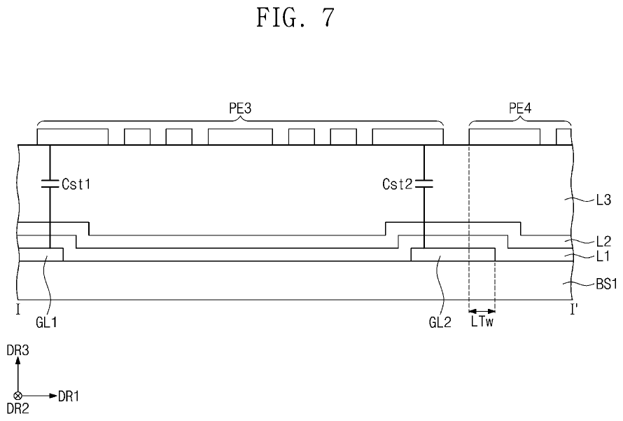

FIG. 7 is a cross-sectional view taken along the line I-I′ illustrated in FIG. 5.

Referring to FIG. 6 and FIG. 7, in a region adjacent to the third pixel electrode PE3, the first gate line GL1 and the second gate line GL2 are disposed. That is, the third gate line GL3 (see FIG. 2) electrically connected to the third pixel electrode PE3 may be disposed to be spaced apart from the third pixel electrode PE3 with one or more pixel electrodes, for example, the fourth pixel electrode PE4, therebetween.

A portion of the third pixel electrode PE3 may overlap with the first gate line GL1 to form a first storage capacitor Cst1, and another portion of the third pixel electrode PE3 may overlap with the second gate line GL2 to form a second storage capacitor Cst2.

That is, according to an embodiment of the inventive concept, even when both sides (i.e., the two sides) of the third pixel electrode PE3 overlap with the first gate line GL1 and the second gate line GL2 (e.g., respectively), the parasitic capacitor Cpc may not be formed between the third pixel electrode PE3 and the first gate line GL1, and between the third pixel electrode PE3 and the second gate line GL2. As a result, the size of the third pixel electrode PE3 may increase so that the aperture ratio and transmittance of the display device DD (see FIG. 1) may be increased.

Even when an overlay deviation of the third pixel electrode PE3 is generated so that an area in which the third pixel electrode PE3 and the first gate line GL1 overlap and an area in which the third pixel electrode PE3 and the second gate line GL3 overlap are changed, the deviation of the kickback voltage Vkb may be minimized or reduced. For example, when the third pixel electrode PE3 is biased (e.g., shifted) in the first direction DR1, an area in which the second gate line GL2 and the third pixel electrode PE3 are overlapped may be increased, and an area in which the first gate line GL1 and the third pixel electrode PE3 are overlapped may be reduced. In this case, the first capacitance of the first storage capacitor Cst1 may decrease and the second capacitance of the second storage capacitor Cst2 may increase. The first and second capacitances can be offset from each other. Thus, the amount of change in the sum of the first and second capacitances can be minimized. Accordingly, the deviation of the kickback voltage Vkb due to the overlay deviation may be minimized or reduced. Thus, a phenomenon in which a residual image or a yellowish color at a low gray scale is viewed on the display device DD (see FIG. 1) may be prevented or substantially prevented.

A width LTw of a region in which a pixel electrode, for example, the fourth pixel electrode PE4 and a gate line, for example, the second gate line GL2 are overlapped may be 3 micrometers or more. The width LTw may be a width in the first direction DR1. When the width LTw is 3 micrometers or more, light leakage occurring between the second gate line GL2 and the fourth pixel electrode PE4 may be prevented or substantially prevented.

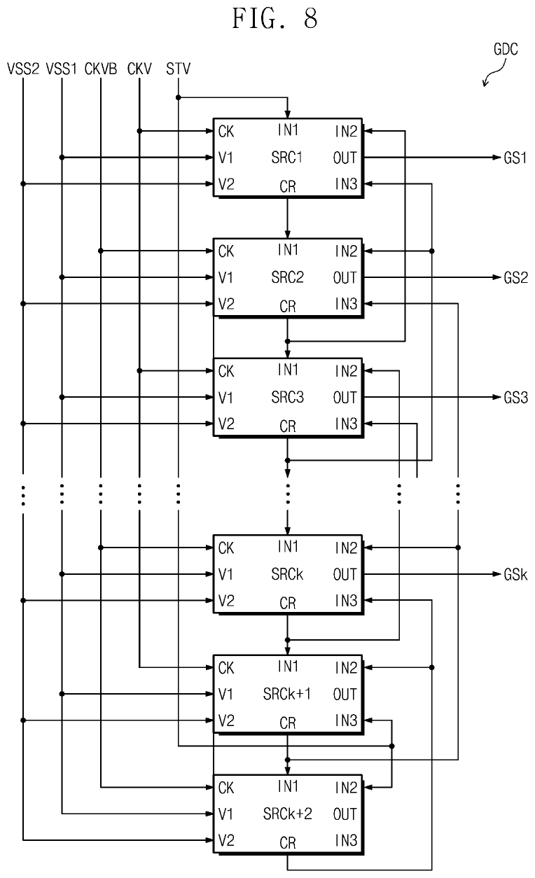

FIG. 8 is a block diagram of a gate driver according to an embodiment of the inventive concept.

Referring to FIG. 8, the gate driver GDV may include a plurality of gate stages SRC1-SRCk and dummy gate stages SRCk+1 and SRCk+2. The plurality of gate stages SRC1-SRCk and the dummy gate stages SRCk+1 and SRCk+2 may have a dependent connection relationship (e.g., may be connected through) operating in response to a carry signal outputted from a previous gate stage and a carry signal outputted from a following gate stage.

The plurality of gate stages SRC1-SRCk may each receive from the signal controller TC (See FIG. 2) a clock signal (a first clock signal CKV or a second clock signal CKVB), and a first ground voltage VSS1 and a second ground voltage VSS2. The first ground voltage VSS1 and the second ground voltage VSS2 may each be referred to as a first voltage and a second voltage. A gate stage SRC1 and the dummy gate stages SRCk+1 and SRCk+2 may further receive a vertical start signal STV.

The plurality of gate stages SRC1-SRCk may provide gate signals GS1-GSk to each of the plurality of gate lines GL1-GLn (see FIG. 2), respectively.

The plurality of gate stages SRC1-SRCk and the dummy gate stages SRCk+1 and SRCk+2 may each have input terminals IN1, IN2 and IN3, an output terminal OUT, a carry terminal CR, a clock terminal CK, a first voltage terminal V1, and a second voltage terminal V2.

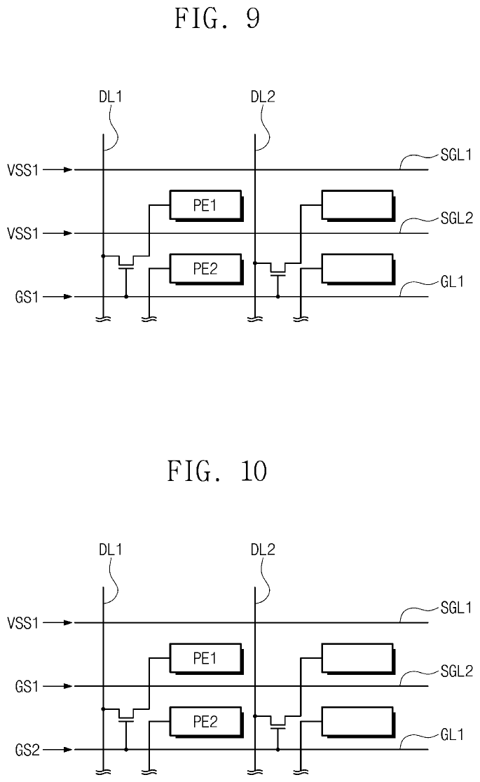

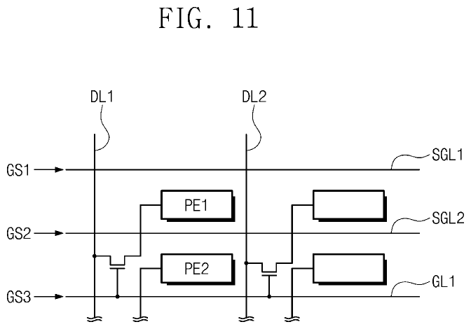

The output terminal OUT of each of the plurality of gate stages SRC1-SRCk may be connected to a corresponding gate line among the plurality of gate lines GL1-GLn (see FIG. 2). The gate signals GS1-GSk generated from the plurality of gate stages SRC1-SRCk may be provided to the plurality of gate lines GL1-GLn through the output terminal OUT. The description thereof will be given in more detail with reference to FIGS. 9 to 10.

The carry terminal CR of each of the plurality of gate stages SRC1-SRCk may be electrically connected to a first input terminal IN1 of a gate stage following the corresponding gate stage. Also, the carry terminal CR of each of the plurality of gate stages SRC1-SRCk may be connected to previous gate stages. For example, the carry terminal CR of a x^{th} gate stage SRCx (wherein, x is a natural number greater than 2) among the gate stages SRC1-SRCk may be connected to a second input terminal IN2 of a x-1^{st} (e.g., (x-1)^{th}) gate stage and a third input terminal IN3 of a x-2^{nd} (e.g., (x-2)^{th}) gate stage. The carry terminal CR of each of the plurality of gate stages SRC1-SRCk and the dummy gate stages SRCk+1 and SRCk+2 may output a carry signal.

The first input terminal IN1 of each of the plurality of gate stages SRC1-SRCk and the dummy gate stages SRCk+1 and SRCk+2 may receive a carry signal of a gate stage before the corresponding gate stage. For example, the first input terminal IN1 of a k^{th} gate stage SRCk may receive a carry signal of a k-1^{st} (e.g., (k-1)^{th}) gate stage SRCk−1. The first input terminal IN1 of a first gate stage SRC1 among the plurality of gate stages SRC1-SRCk may receive the vertical start signal STV for initiating driving of the gate driver GDV instead of a carry signal of a previous gate stage.

The second input terminal IN2 of each of the plurality of gate stages SRC1-SRCk may receive a carry signal from the carry terminal CR of a gate stage following the corresponding gate stage. The third input terminal IN3 of each of the plurality of gate stages SRC1-SRCk may receive a carry signal of a gate stage following the next stage of the corresponding gate stage. For example, the second input terminal IN2 of the k^{th} gate stage SRCk may receive a carry signal outputted from the carry terminal CR of a dummy gate stage SRCk+1. The third input terminal IN3 of the k^{th} gate stage SRCk may receive a carry signal outputted from the carry terminal CR of a dummy gate stage SRCk+2. In another embodiment of the inventive concept, the second input terminal IN2 of each of the plurality of gate stages SRC1-SRCk may be electrically connected to the output terminal OUT of a gate stage following the corresponding gate stage. Also, the third input terminal IN3 of each of the plurality of gate stages SRC1-SRCk may be electrically connected to the output terminal OUT of a gate stage following the next stage of the corresponding stage.

The second input terminal IN2 of the gate stage SRCk disposed at an end receives a carry signal outputted from the carry terminal CR of the dummy gate stage SRCk+1. The third input terminal IN3 of the gate stage SRCk receives a carry signal outputted from the carry terminal CR of the dummy gate stage SRCk+2.

The clock terminal CK of each of the plurality of gate stages SRC1-SRCk may receive any one of the first clock signal CKV and the second clock signal CKVB, respectively. The clock terminals CK of odd-numbered gate stages SRC1, SRC3, . . . , SRCk−1 of the plurality of gate stages SRC1-SRCk may receive the first clock signal CKV, respectively. The clock terminals CK of even-numbered gate stages SRC2, SRC4, . . . , SRCk of the plurality of gate stages SRC1-SRCk may receive the second clock signal CKVB, respectively. The first clock signal CKV and the second clock signal CKVB may be signals having different phases. In this embodiment, the first clock signal CKV and the second clock signal CKVB are complementary signals.

The first voltage terminal V1 of each of the plurality of gate stages SRC1-SRCk receives the first ground voltage VSS1. The second voltage terminal V2 of each of the plurality of gate stages SRC1-SRCk receives the second ground voltage VSS2. The first ground voltage VSS1 and the second ground voltage VSS2 have different voltage levels. In this embodiment, the second ground voltage VSS2 has a level lower than the first ground voltage VSS1.

In an embodiment of the inventive concept, in each of the plurality of gate stages SRC1-SRCk, any one of the output terminal OUT, the first input terminal IN1, the second input terminal IN2, the third input terminal IN3, the carry terminal CR, the clock terminal CK, the first voltage terminal V1, and the second voltage terminal V2 may be omitted (i.e., may not be included), or other terminals may be further included. For example, any one of the first voltage terminal V1 and the second voltage terminal V2 may be omitted. In this case, each of the plurality of gate stages SRC1-SRCk receives only one of the first ground voltage VSS1 and the second ground voltage VSS2. Also, the connection relationship of the plurality of gate stages SRC1-SRCk may be changed.

FIG. 9 is a block diagram showing an enlarged view of a portion of a display panel according to an embodiment of the inventive concept.

Referring to FIG. 8 and FIG. 9, a first gate signal GS1 outputted from the first gate stage SRC1 may be outputted to the first gate line GL1. The first gate line GL1 may be a gate line electrically connected to a first pixel electrode PE1.

To the first auxiliary gate line SGL1 and the second auxiliary gate line SGL2 spaced apart from each other with the first pixel electrode PE1 therebetween, the first ground voltage VSS1 may be provided.

According to an embodiment of the inventive concept, the number of the plurality of gate stages SRC1-SRCk may be equal to the number of the gate lines GL1-GLn. For example, k may be equal to n.

According to an embodiment of the inventive concept, as the first ground voltage VSS1 may be provided to the first auxiliary gate line SGL1 and the second auxiliary gate line SGL2, a kickback voltage component may not be generated in the first pixel electrode PE1. The kickback voltage component may be, for example, the parasitic capacitor Cpc illustrated in FIG. 6. Accordingly, the display quality of the display device DD (see FIG. 1) may be improved.

FIG. 10 is a block diagram showing an enlarged view of a portion of a display panel according to an embodiment of the inventive concept.

Referring to FIG. 8 and FIG. 10, the first ground voltage VSS1 may be outputted to the first auxiliary gate line SGL1, and the first gate signal GS1 outputted from the first gate stage SRC1 may be outputted to the second auxiliary gate line SGL2. The second auxiliary gate line SGL2 may be a line disposed between the first pixel electrode PE1 and the second pixel electrode PE2. A second gate signal GS2 outputted from a second gate stage SRC2 may be outputted to the first gate line GL1.

According to an embodiment of the inventive concept, to the first gate line GL1 connected to the first pixel electrode PEI, the second gate signal GS2 shifted by a first horizontal period with respect to the first gate signal GS1 is inputted. Accordingly, when compared with FIG. 9, a pixel voltage provided through the first data line DL1 may be provided to be shifted by the first horizontal period. The first horizontal period may indicate a period of time obtained by dividing the time representing one frame by n when the display panel DP (see FIG. 2) includes n gate lines GL1-GLn (see FIG. 2).

According to an embodiment of the inventive concept, the number of the plurality of gate stages SRC1-SRCk may be greater than the number of the gate lines GL1-GLn. For example, k may be equal to n+1.

According to an embodiment of the inventive concept, a gate signal generated from a gate stage may be provided to the second auxiliary gate line SGL2, like the same signal (e.g., similar to the gate signal) provided to other gate lines. Accordingly, gate signals are provided to each of the lines adjacent to the second pixel electrode PE2, the second auxiliary gate line SGL2, and the first gate line GL1. As a result, the magnitude of the kickback voltage Vkb generated in the second pixel electrode PE2 may have a value similar to that of a kickback voltage generated in other pixel electrodes.

When the kickback voltages applied to the pixels providing the same color are different from each other, a luminance difference may occur between the pixels. However, according to an embodiment of the inventive concept, a gate signal is provided to the second auxiliary gate line SGL2 and the first gate line GL1 overlapping with the second pixel electrode PE2, and a gate signal is provided to the third gate line GL3 (see FIG. 2) and a fourth gate line GL4 (see FIG. 2) overlapping with the fifth pixel electrode PES. Accordingly, the difference between a kickback voltage generated in the second pixel electrode PE2 and a kickback voltage generated in the fifth pixel electrode PE5 may be minimized or reduced. Therefore, a second pixel which provides green light and a fifth pixel which provides green light may provide light with the same or substantially the same luminance. The second pixel may be a pixel including the second pixel electrode PE2, and the fifth pixel may be a pixel including the fifth pixel electrode PE5.

FIG. 11 is a block diagram showing an enlarged view of a portion of a display panel according to an embodiment of the inventive concept.

Referring to FIG. 8 and FIG. 11, the first gate signal GS1 outputted from the first gate stage SRC1 may be outputted to the first auxiliary gate line SGL1, and the second gate signal GS2 outputted from the second gate stage SRC2 may be outputted to the second auxiliary gate line SGL2. A third gate signal GS3 outputted from a third gate stage SRC3 may be outputted to the first gate line GL1.

According to an embodiment of the inventive concept, to the first gate line GL1 connected to the first pixel electrode PE1, the third gate signal GS3 shifted by a second horizontal period with respect to the first gate signal GS1 is inputted. Accordingly, when compared with FIG. 9, a pixel voltage provided through the first data line DL1 may be provided to be shifted by the second horizontal period. The second horizontal period may indicate a period of time obtained by dividing the time representing one frame by n and then multiplying the same by 2 when the display panel DP (see FIG. 2) includes n gate lines GL1-GLn (see FIG. 2).

According to an embodiment of the inventive concept, the number of the plurality of gate stages SRC1-SRCk may be greater than the number of the gate lines GL1-GLn. For example, k may be equal to n+2.

According to the inventive concept, a gate line electrically connected to a pixel electrode may not overlap with the pixel electrode (e.g., when viewed on a plane). Accordingly, a parasitic capacitor (parasitic capacitance) generated between the gate line and the pixel electrode may be minimized or reduced so that the magnitude of a kickback voltage may be reduced and the display quality of a display device may be improved.

In addition, according to the inventive concept, a pixel electrode may overlap with adjacent gate lines electrically connected to an adjacent pixel electrode, which is spaced apart from the pixel electrode, when viewed on a plane. Accordingly, even when the pixel electrode and an adjacent gate line overlap with each other, and a storage capacitor is formed between the pixel electrode and the adjacent gate line, a parasitic capacitor may not be formed therebetween. Accordingly, even when an overlapping area of the pixel electrode and the adjacent gate line is increased by increasing the area of the pixel electrode, the magnitude of a kickback voltage may not increase. In addition, as the area of the pixel electrode is increased, the aperture ratio and transmittance of the display device may be increased.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents and shall not be restricted or limited by the foregoing detailed description.

What is claimed is:

1. A display device comprising:
a first pixel electrode;
a second pixel electrode spaced apart from the first pixel electrode in a first direction;
a third pixel electrode spaced apart from the second pixel electrode in the first direction;
a first gate line electrically connected to the first pixel electrode;
a second gate line electrically connected to the second pixel electrode; and
a third gate line electrically connected to the third pixel electrode,
wherein the first gate line is between the second pixel electrode and the third pixel electrode.

2. The display device of claim 1, wherein the first pixel electrode does not overlap with the first gate line when viewed on a plane.

3. The display device of claim 1, wherein the third pixel electrode overlaps with the first gate line and the second gate line when viewed on a plane.

4. The display device of claim 3, further comprising:
a first storage capacitor between the third pixel electrode and the first gate line, and
a second storage capacitor between the third pixel electrode and the second gate line.

5. The display device of claim 1, wherein the first gate line overlaps with the second pixel electrode and the third pixel electrode when viewed on a plane.

6. The display device of claim 1, further comprising a first auxiliary gate line and a second auxiliary gate line facing each other and with the first pixel electrode therebetween.

7. The display device of claim 6, wherein each of the first auxiliary gate line, the second auxiliary gate line, the first gate line, the second gate line, and the third gate line is extended in a second direction crossing the first direction.

8. The display device of claim 6, further comprising a gate driver configured to provide a gate signal to each of the first gate line, the second gate line, and the third gate line,
wherein the gate driver comprises a plurality of gate stages.

9. The display device of claim 8, wherein the first gate line, the second gate line, and the third gate line are electrically connected to the plurality of gate stages in a one-to-one correspondence, and each of the first auxiliary gate line and the second auxiliary gate line is configured to receive a ground voltage.

10. The display device of claim 8, wherein the second auxiliary gate line is between the first pixel electrode and the second pixel electrode, electrically connected to one gate stage among the plurality of gate stages, and configured to receive the gate signal.

11. The display device of claim 1 further comprising:
a fourth pixel electrode spaced apart from the third pixel electrode in the first direction;
a fifth pixel electrode spaced apart from the fourth pixel electrode in the first direction;
a sixth pixel electrode spaced apart from the fifth pixel electrode in the first direction;
a first data line electrically connected to the first pixel electrode, the second pixel electrode, and the third pixel electrode, and configured to receive a data voltage of a first polarity; and
a second data line electrically connected to the fourth pixel electrode, the fifth pixel electrode, and the sixth pixel electrode, and configured to receive a data voltage of a second polarity different from the first polarity, wherein
the first data line and the second data line comprise a first partial line extended in the first direction, a second partial line extended from the first partial line in a second direction crossing the first direction, and a third partial line extended from the second partial line in the first direction, and the second partial line is in a region between the fourth pixel electrode and the fifth pixel electrode.

12. The display device of claim 11, wherein
the second gate line is between the third pixel electrode and the fourth pixel electrode and overlaps with the third pixel electrode and the fourth pixel electrode when viewed on a plane, and
the third gate line is between the fourth pixel electrode and the fifth pixel electrode and overlaps with the fourth pixel electrode and the fifth pixel electrode when viewed on a plane.

13. The display device of claim 1, wherein a first width of the first pixel electrode parallel to the first direction is less than a second width of the first pixel electrode parallel to a second direction crossing the first direction.

14. The display device of claim 1, wherein the first pixel electrode comprises a first boundary electrode extended in a second direction crossing the first direction, a second boundary electrode extended in the first direction, and a plurality of branch electrodes extended from a corresponding one of the first boundary electrode and the second boundary electrode in a direction crossing the first direction and the second direction.

15. The display device of claim 14, wherein a length of the first boundary electrode is greater than a length of the second boundary electrode.

16. A display device comprising:
a plurality of pixel electrodes arranged with each other along a first direction;
a plurality of pixel transistors electrically connected to the plurality of pixel electrodes in a one-to-one correspondence; and
a plurality of gate lines electrically connected to the plurality of pixel transistors in a one-to-one correspondence, wherein
the plurality of pixel electrodes comprise a first pixel electrode and a second pixel electrode,
the plurality of pixel transistors comprise a first pixel transistor electrically connected to the first pixel electrode and a second pixel transistor electrically connected to the second pixel electrode,
the plurality of gate lines comprise a first gate line electrically connected to the first pixel transistor and a second gate line electrically connected to the second pixel transistor,
the first pixel transistor is adjacent to the second pixel electrode, and
the first gate line is spaced apart from the first pixel electrode and with the second pixel electrode therebetween.

17. The display device of claim 16, further comprising a first auxiliary gate line and a second auxiliary gate line facing each other and with the first pixel electrode therebetween.

18. The display device of claim 17, wherein the plurality of gate lines are configured to receive a gate signal, and the first auxiliary gate line and the second auxiliary gate line are configured to receive a ground voltage.

19. The display device of claim 17, wherein
the second auxiliary gate line is between the first pixel electrode and the second pixel electrode and overlaps with the first pixel electrode and the second pixel electrode when viewed on a plane,
the plurality of gate lines and the second auxiliary gate line are configured to receive a gate signal, and
the first auxiliary gate line is configured to receive a ground voltage.

20. The display device of claim 16, wherein the first pixel electrode comprises:
a first boundary electrode extended in a second direction crossing the first direction,
a second boundary electrode extended in the first direction, and
a plurality of branch electrodes extended from each of the first boundary electrode and the second boundary electrode in a direction crossing the first direction and the second direction, and
a length of the first boundary electrode is greater than a length of the second boundary electrode.
